(19) United States
(12) Patent Application Publication
(10) Pub. No.: US 2026/0205092 A1
(43) Pub. Date: Jul. 16, 2026

(54) RESONATOR ELEMENT AND RESONATOR DEVICE

(71) Applicant: SEIKO EPSON CORPORATION, Tokyo (JP)

(72) Inventor: Naohisa Obata, Minowa-machi (JP)

(21) Appl. No.: 19/444,872

(22) Filed: Jan. 9, 2026

(30) Foreign Application Priority Data
Jan. 10, 2025 (JP) 2025-003945

(51) Int. Cl. H03H 9/13; H03H 9/17

(52) U.S. Cl. CPC H03H 9/13; H03H 9/17

(57) ABSTRACT

A resonator element includes a quartz crystal substrate having a first surface along an X-axis and a Z'-axis of a quartz crystal and having a quadrangular shape in plan view including a first outer edge intersecting the X-axis, a first excitation electrode disposed on the first surface of the quartz crystal substrate and having a quadrangular shape in plan view including a first side intersecting the X-axis, a first mount electrode disposed on a side of the first outer edge of the quartz crystal substrate and connected to the first excitation electrode, and a first lead-out electrode connecting the first excitation electrode and the first mount electrode. The resonator element has a non-electrode region, in which the quartz crystal substrate is exposed, between the first outer edge of the quartz crystal substrate and the first side of the first excitation electrode.

The present application is based on, and claims priority from JP Application Serial Number 2025-003945, filed January 10, 2025, the disclosure of which is hereby incorporated by reference herein in its entirety.

### BACKGROUND

### 1. Technical Field

The present disclosure relates to a resonator element and a resonator device.

### 2. Related Art

JP-A-2014-175811 discloses a configuration of a quartz crystal resonator element in which an excitation electrode and a routing pattern connected to the excitation electrode is provided on both main surfaces of a quartz crystal element, and in the excitation electrode, an outline on a side on which the routing pattern is provided is formed in a curved line. Since the excitation electrode is formed in a curved shape, the area of the excitation electrode can be secured even when a quartz crystal resonator is miniaturized, and a CI (crystal impedance) value can be reduced.

However, although the CI value can be reduced by the configuration described in JP-A-2014-175811, there is a problem in that a spurious resonance mode (unnecessary oscillation other than main oscillation) and a Q value (quality factor) are not considered at all.

### SUMMARY

A resonator element includes: a quartz crystal substrate having a surface along an X-axis and a Z'-axis of a quartz crystal and having a quadrangular shape in plan view including a first outer edge intersecting the X-axis; an excitation electrode disposed on the surface of the quartz crystal substrate and having a quadrangular shape in plan view including a first side intersecting the X-axis; a mount electrode disposed on a side of the first outer edge of the quartz crystal substrate and connected to the excitation electrode; and an lead-out electrode connecting the excitation electrode and the mount electrode. The resonator element has a non-electrode region, in which the quartz crystal substrate is exposed, between the first outer edge of the quartz crystal substrate and the first side of the excitation electrode.

A resonator device includes the resonator element described above and a base substrate to which the resonator element is attached.

### BRIEF DESCRIPTION OF THE DRAWINGS

FIG. 1 is a plan view showing a configuration of the resonator device.

FIG. 2 is a cross-sectional view taken along a line II-II of the resonator device shown in FIG. 1.

FIG. 3 is a plan view showing a configuration of the resonator element constituting the resonator device.

FIG. 4 is a perspective view showing a configuration of the resonator element.

FIG. 5 is an enlarged plan view showing a portion B of the resonator element shown in FIG. 3.

FIG. 6 is a graph showing a relationship between the width of the lead-out electrode and Q values.

FIG. 7A is a plan view showing a configuration of another resonator element.

FIG. 7B is a plan view showing a configuration of another resonator element.

FIG. 8A is a plan view showing a state of spurious resonance mode generated in a resonator element according to the related art.

FIG. 8B is a plan view showing a state of spurious resonance mode generated in a resonator element according to the embodiment.

FIG. 9 is a graph comparatively showing Q values of resonator elements.

### DESCRIPTION OF EMBODIMENTS

Hereinafter, configurations of a resonator element 10 and a resonator device 1 will be described with reference to the drawings. In each of the following figures, three axes orthogonal to each other are referred to as an X-axis, a Y'-axis, and a Z'-axis. A direction along the X-axis is referred to as an "X-axis direction", a direction along the Y'-axis is referred to as a "Y'-axis direction", and a direction along the Z'-axis is referred to as a "Z'-axis direction", and a direction of an arrow is referred to as a + direction, and a direction opposite to the + direction is referred to as a - direction. In addition, a plane parallel to the X-axis and the Y'-axis is referred to as an "XY' plane", a plane parallel to the X-axis and the Z'-axis is referred to as an "XZ' plane", and a plane parallel to the Y'-axis and the Z'-axis is referred to as a "Y'Z' plane". A plan view from the + Y'-axis direction is simply referred to as a "plan view".

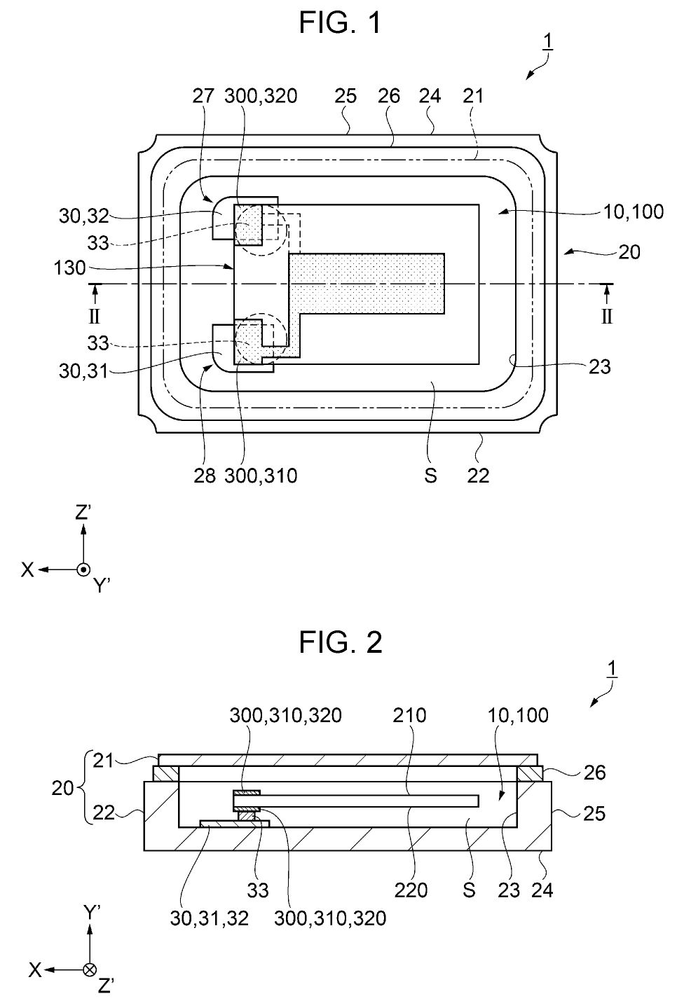

First, the configuration of the resonator device 1 will be described with reference to FIGS. 1 and 2. The resonator device 1 shown in FIG. 1 is in a state where a lid 21 (refer to FIG. 2) is removed.

As shown in FIGS. 1 and 2, the resonator device 1 is a surface mount component in which the resonator element 10 is packaged. In the present embodiment, a resonator will be described as an example of the resonator device 1.

The resonator device 1 includes a resonator element 10 and a package 20.

The package 20 includes a container 22 and a lid 21. The container 22 is a box-shaped member in which a recess portion 23 is formed. An internal space S of the package 20 is defined by bonding the container 22 and the lid 21. The resonator element 10 is accommodated in the internal space S of the package 20.

The container 22 includes a base substrate 24 which is a bottom portion of the recess portion 23, a frame-shaped frame portion 25 disposed on the base substrate 24, and a mounting pad 30 as a terminal on which the resonator element 10 is mounted. The container 22 has a substantially rectangular shape having a pair of sides along the X-axis direction and a pair of sides along the Z'-axis direction in plan view. The recess portion 23 of the container 22 is open to the + Y' side.

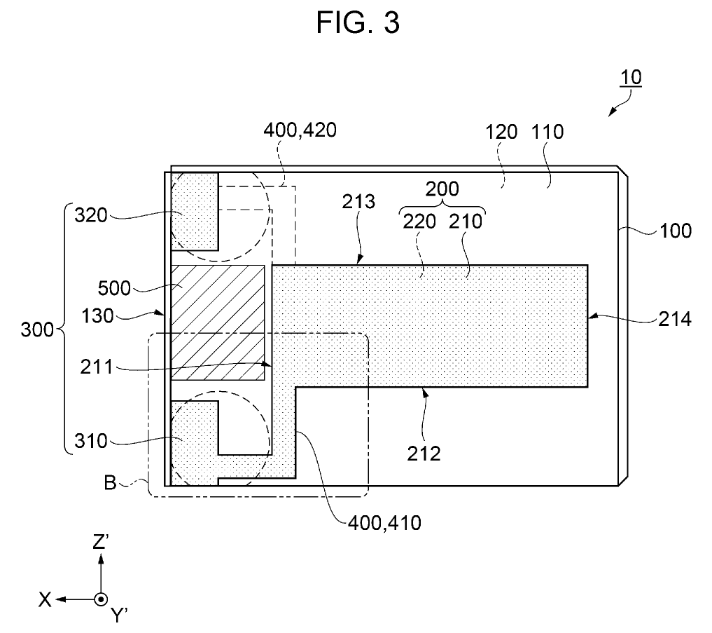

The mounting pad 30 is fixed to a quartz crystal substrate 100 via a bonding member 33. Specifically, a first excitation electrode 210 is provided on a first surface 110 (refer to FIG. 3) of the quartz crystal substrate 100. The first excitation electrode 210 is electrically connected to the bonding member 33 via a mount electrode 300.

A second excitation electrode 220 is provided on a second surface 120 (refer to FIG. 3) of the quartz crystal substrate 100. The second excitation electrode 220 is electrically connected to the bonding member 33 via the mount electrode 300.

As described above, the mount electrode 300 is electrically connected to an excitation electrode 200, and is disposed on a side of a first outer edge 130 of the quartz crystal substrate 100. The mount electrode 300 includes a first mount electrode 310 electrically connected to the first excitation electrode 210 and a second mount electrode 320 electrically connected to the second excitation electrode 220.

The mounting pad 30 includes a first mounting pad 31 and a second mounting pad 32. The first mounting pad 31 is disposed at a corner portion 28 on the + X side and the - Z' side of the recess portion 23. The second mounting pad 32 is disposed at a corner portion 27 on the + X side and the + Z' side of the recess portion 23.

In the container 22, an external electrode (not shown) is provided on a surface of the base substrate 24 opposite to a surface on which the mounting pad 30 is disposed. The external electrode is electrically connected to the mounting pad 30 by a wiring inside the base substrate 24.

A material of the base substrate 24 and the frame portion 25 is not particularly limited, but is, for example, an insulating material. Examples of the insulating material include various ceramics such as alumina.

The lid 21 is substantially rectangular in plan view, and has a plate shape parallel to the XZ' plane. The lid 21 is bonded to the opening of the container 22 via a sealing material 26 to seal the recess portion 23. The sealing material 26 may be referred to as a seal ring.

As a base material of the constituent material of the lid 21, Kovar is used. Kovar is plated with nickel (Ni). However, the material of the lid 21 is not limited thereto, and may be, for example, Alloy 42, stainless steel, glass, ceramic, or silicon.

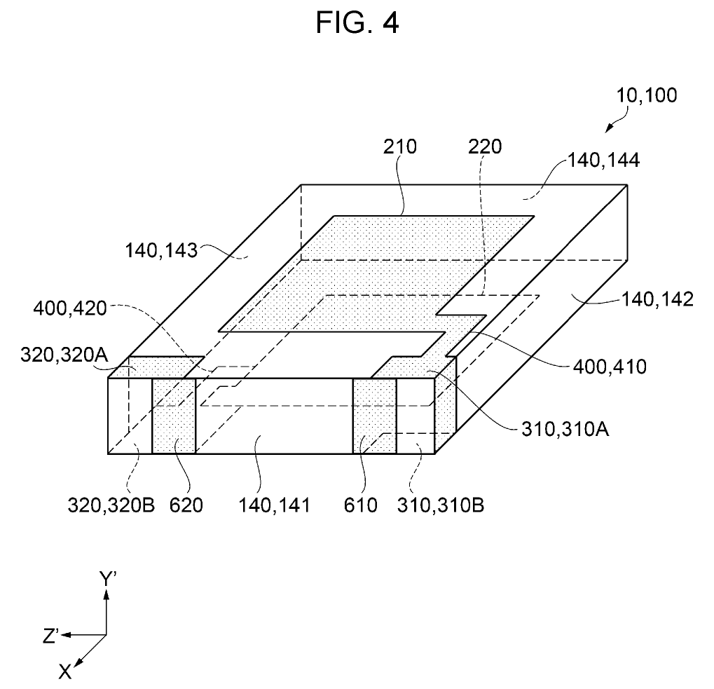

Next, the configuration of the resonator element 10 will be described with reference to FIGS. 3 and 4.

As shown in FIGS. 3 and 4, the resonator element 10 is configured with the quartz crystal substrate 100 made of quartz crystal, and has a plane along the X-axis and the Z'-axis of the quartz crystal, that is, an XZ' plane. The resonator element 10 is formed in a quadrangular plate shape in plan view parallel to the XZ' plane. The resonator element 10 has the first outer edge 130 intersecting the X-axis, that is, along the Z'-axis.

The resonator element 10 includes the quartz crystal substrate 100, the excitation electrode 200 disposed on the quartz crystal substrate 100, the mount electrode 300, and an lead-out electrode 400 that electrically connects the excitation electrode 200 and the mount electrode 300.

The quartz crystal substrate 100 includes the first surface 110 and the second surface 120 that are parallel to the XZ' plane and have a front-back relationship with each other. The first surface 110 and the second surface 120 are AT cut surfaces of quartz crystal.

The excitation electrode 200 includes the first excitation electrode 210 provided on the first surface 110 and the second excitation electrode 220 provided on the second surface 120.

The first excitation electrode 210 is formed in a quadrangular shape in plan view, and has a first side 211 intersecting the X-axis, that is, along the Z'-axis, a second side 212 and a third side 213 intersecting the first side 211, and a fourth side 214 facing the first side 211 and intersecting the second side 212 and the third side 213.

The mount electrode 300 is electrically connected to the excitation electrode 200, and is disposed on the side of the first outer edge 130 of the quartz crystal substrate 100. The mount electrode 300 includes the first mount electrode 310 electrically connected to the first excitation electrode 210 and the second mount electrode 320 electrically connected to the second excitation electrode 220.

Between the first outer edge 130 of the quartz crystal substrate 100 and the first side 211 of the first excitation electrode 210, a non-electrode region 500, in which the quartz crystal substrate 100 is exposed, is provided. Specifically, the non-electrode region 500 is a region where, for example, the excitation electrode 200, the mount electrode 300, the lead-out electrode 400, and the like are not formed.

The first mount electrode 310 is disposed on one side in the Z'-axis direction of the non-electrode region 500. The second mount electrode 320 is disposed on the other side in the Z'-axis direction of the non-electrode region 500.

The lead-out electrode 400 includes a first lead-out electrode 410 that electrically connects the first excitation electrode 210 and the first mount electrode 310, and a second lead-out electrode 420 that electrically connects the second excitation electrode 220 and the second mount electrode 320.

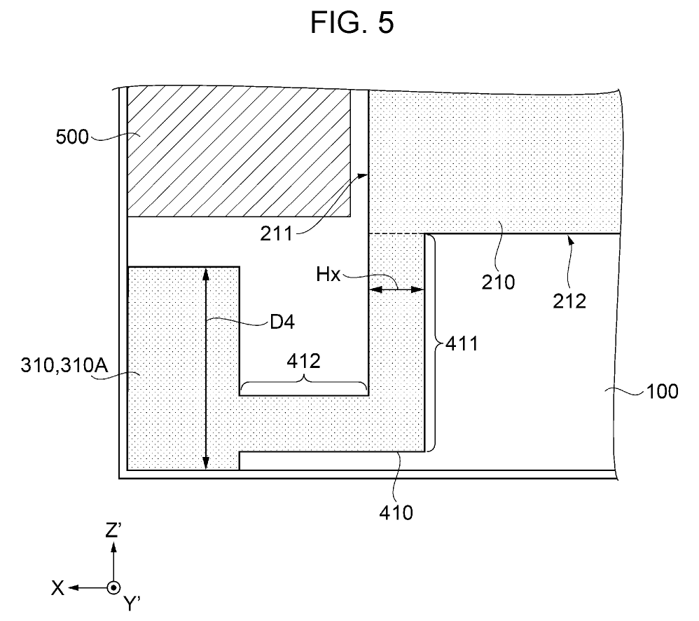

The first lead-out electrode 410 includes a first portion 411 extending from the second side 212 along the Z'-axis and a second portion 412 extending from the first portion 411 along the X-axis and connected to the first mount electrode 310 (refer to FIG. 5).

As described above, since the non-electrode region 500, in which the quartz crystal substrate 100 is exposed, is provided between the first outer edge 130 and the first side 211, in other words, since the first lead-out electrode 410 having the first portion 411 and the second portion 412 is not provided between the first outer edge 130 and the first side 211, even when a spurious resonance mode is generated in the quartz crystal substrate 100, the first lead-out electrode 410 is not easily affected by the spurious resonance mode. That is, the first lead-out electrode 410 is not coupled to the spurious resonance mode. Therefore, it is possible to suppress leakage of vibrational energy from the first lead-out electrode 410 to, for example, the mount electrode 300, and it is possible to obtain a stable Q value.

Similarly, the first mount electrode 310 and the second mount electrode 320 are disposed so as not to overlap the non-electrode region 500, which is easily affected by the spurious resonance mode, in plan view. Further, the bonding member 33 is also disposed at a position not overlapping the non-electrode region 500 in plan view. As a result, even when a spurious resonance mode is generated in the quartz crystal substrate 100, the mount electrodes 310 and 320 and the bonding member 33 are not easily affected by the spurious resonance mode. Therefore, it is possible to suppress variations in Q values in the resonator element 10.

The Q value indicates a value of a maximum amplitude in oscillation. In other words, the Q value indicates a difference between oscillation and noise, and it is preferable to be a large value. That is, a numerical value with less noise is preferable.

As shown in FIG. 4, the resonator element 10 includes the quartz crystal substrate 100 as described above. The first excitation electrode 210, the first lead-out electrode 410, and a first mount electrode 310A are provided on the first surface 110 of the quartz crystal substrate 100. Further, a second mount electrode 320A electrically connected to the second excitation electrode 220 is provided on the first surface 110.

The second excitation electrode 220, the second lead-out electrode 420, and a second mount electrode 320B are provided on the second surface 120 of the quartz crystal substrate 100. Further, a first mount electrode 310B electrically connected to the first excitation electrode 210 is provided on the second surface 120.

The quartz crystal substrate 100 has a side surface 140 that connects the first surface 110 and the second surface 120. The side surface 140 includes a first side surface 141 along the first outer edge 130, a second side surface 142 and a third side surface 143 intersecting the first side surface 141, and a fourth side surface 144 facing the first side surface 141 and intersecting the second side surface 142 and the third side surface 143.

The first side surface 141 is provided with a first side surface electrode 610 that electrically connects the first mount electrode 310A of the first surface 110 and the first mount electrode 310B of the second surface 120. The first side surface electrode 610 may be provided on the second side surface 142. In addition, the first side surface 141 is provided with a second side surface electrode 620 that electrically connects the second mount electrode 320A of the first surface 110 and the second mount electrode 320B of the second surface 120. The second side surface electrode 620 may be provided on the third side surface 143.

The resonator element 10 is attached to the base substrate 24 by being connected to the mounting pad 30 (refer to FIG. 1) via the bonding member 33. Specifically, the first mounting pad 31 is electrically connected to the first mount electrode 310B via the bonding member 33. The second mounting pad 32 is electrically connected to the second mount electrode 320B via the bonding member 33. The bonding member 33 has conductivity.

A voltage is supplied to the resonator device 1 from an external terminal (not shown). The supplied voltage is applied to the first excitation electrode 210 via the first mounting pad 31, the bonding member 33, and the first mount electrodes 310A and 310B. Further, the supplied voltage is applied to the second excitation electrode 220 via the second mounting pad 32, the bonding member 33, and the second mount electrode 320B. When a voltage is applied to the first excitation electrode 210 and the second excitation electrode 220, oscillation is excited, and the resonator element 10 oscillates.

The mount electrodes 310A, 310B, 320A, and 320B include tungsten (W) as a base material layer and a nickel (Ni) plating layer as a front surface layer. A constituent material of the mount electrodes 310A, 310B, 320A, and 320B is not particularly limited; for example, the base material layer may be molybdenum (Mo), and the front surface layer may be gold (Au).

The second excitation electrode 220, the second lead-out electrode 420, and the second mount electrode 320B provided on the second surface 120 of the quartz crystal substrate 100 are disposed having the same shape as the first excitation electrode 210, the first lead-out electrode 410, and the first mount electrode 310A, although the orientation thereof is different from that on the first surface 110.

Next, the configuration of the first lead-out electrode 410 will be described in detail with reference to FIGS. 5, 6, 7A, and 7B.

As shown in FIG. 5, as described above, the first lead-out electrode 410 includes the first portion 411 extending from the second side 212 along the - Z'-axis and the second portion 412 extending from the first portion 411 along the X-axis and connected to the first mount electrode 310.

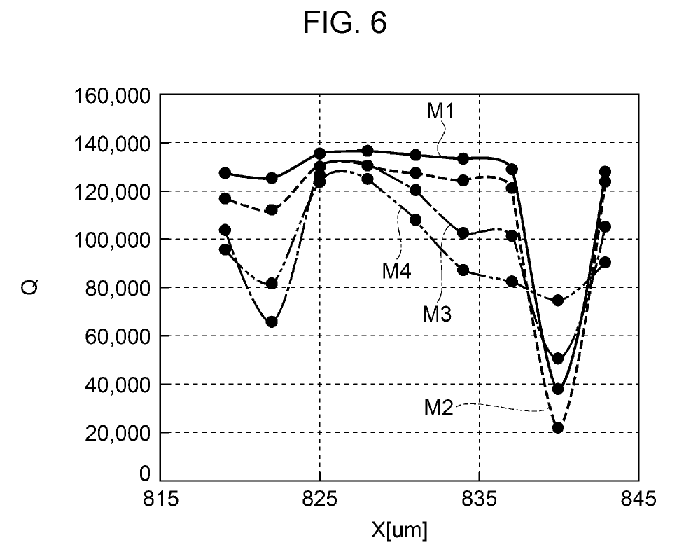

The graph shown in FIG. 6 shows relationships between wiring widths of the first lead-out electrode 410 and Q values of the resonator element 10. The horizontal axis of the graph indicates the positions of the resonator element 10 in the X-axis direction. The vertical axis of the graph indicates the Q values. The wiring widths M1 to M4 have different widths of the first lead-out electrode 410. The wiring width M1 of the first lead-out electrode 410 is the narrowest. The wiring width M2 is wider than the wiring width M1 of the first lead-out electrode 410. The wiring width M3 is wider than the wiring width M2 of the first lead-out electrode 410. The wiring width M4 of the first lead-out electrode 410 is the widest.

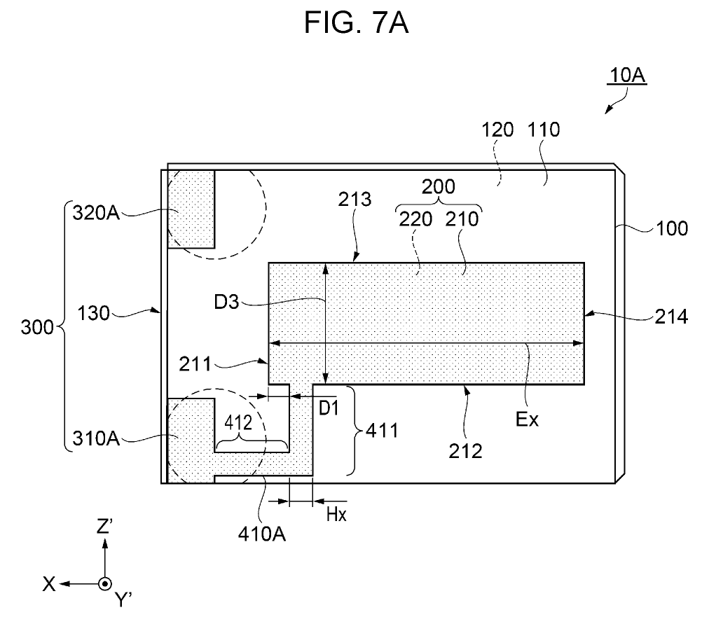

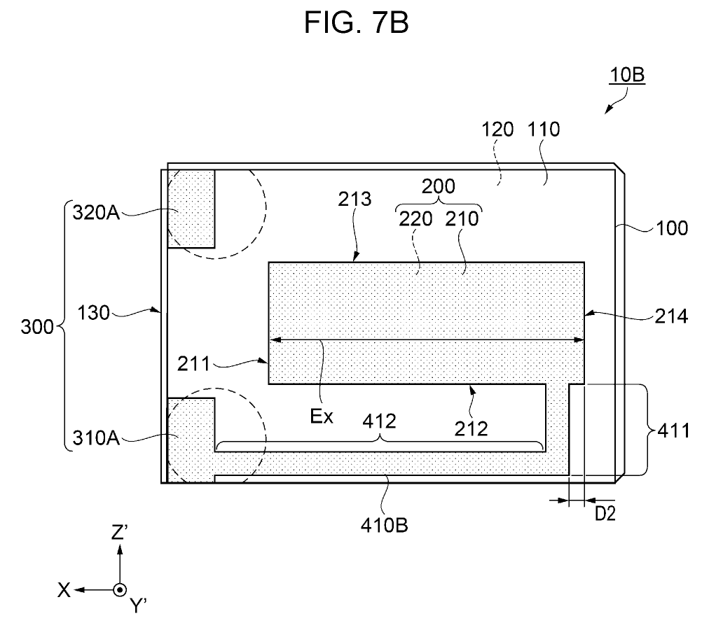

As indicated by the wiring width M1 in the graph of FIG. 6, when the width of the first lead-out electrode 410 is narrow, a high Q value can be obtained as a whole, although a low Q value is indicated in some positions. On the other hand, it is found that, as the width of the first lead-out electrode 410 becomes wider toward the wiring width M4, the influence of the spurious resonance mode becomes weaker, but the Q values decrease as a whole. Based on this result, the positions and widths of the first lead-out electrode 410 in FIGS. 5, 7A, and 7B are defined to obtain Q values closer to those in the wiring width M1.

As shown in FIG. 7A, in the resonator element 10A, a length of the first excitation electrode 210 in the X-axis direction is denoted by Ex, and a distance between the first portion 411 of the first lead-out electrode 410A and the first side 211 of the first excitation electrode 210 in the X-axis direction is denoted by D1. In this case, it is preferable to set D1 so as to satisfy a relationship of 0≤D1/Ex≤0.18. That is, it is preferable that the first lead-out electrode 410A is extracted from a region where an oscillation is small in the first excitation electrode 210.

Further, as shown in FIG. 7B, in the resonator element 10B, a length of the first excitation electrode 210 in the X-axis direction is denoted by Ex, and a distance between the first portion 411 of the first lead-out electrode 410B and the fourth side 214 of the first excitation electrode 210 in the X-axis direction is denoted by D2. In this case, it is preferable to set D2 so as to satisfy a relationship of 0≤D2/Ex≤0.18. That is, it is preferable that the first lead-out electrode 410B is extracted from a region where an oscillation is small in the first excitation electrode 210.

Further, as shown in FIG. 7A, it is preferable that a length Hx of the first portion 411 of the first lead-out electrode 410A in the X-axis direction is shorter than a length D3 of the first excitation electrode 210 in the Z'-axis direction. According to this configuration, since the length of the first portion 411 of the first lead-out electrode 410A in the X-axis direction is shorter than the length of the first excitation electrode 210 in the Z'-axis direction, that is, since the width of the first lead-out electrode 410A is narrow, the Q value can be increased.

Further, as shown in FIG. 5, it is preferable that the length Hx of the first portion 411 of the first lead-out electrode 410 in the X-axis direction is shorter than a length D4 of the first mount electrode 310A in the Z'-axis direction. According to this configuration, since the length Hx of the first portion 411 of the first lead-out electrode 410 in the X-axis direction is shorter than the length D4 of the first mount electrode 310A in the Z'-axis direction, that is, since the width of the first lead-out electrode 410 is narrow, the Q value can be increased. In addition, it is possible to increase the size of the first mount electrode 310A to the extent that the first mount electrode 310A does not overlap the non-electrode region 500, and for example, the conductivity with the bonding member 33 can be increased.

In addition, as shown in FIG. 7A, when a length of the first excitation electrode 210 in the X-axis direction is denoted by Ex and a length of the first portion 411 of the first lead-out electrode 410A in the X-axis direction is denoted by Hx, it is preferable to satisfy a relationship of 0<Hx/Ex≤0.18.

The length Ex of the first excitation electrode 210 in the X-axis direction is, for example, 562 μm. The length Hx of the first lead-out electrode 410A in the X-axis direction is, for example, 100 μm or less. According to this configuration, since the first lead-out electrode 410 is set so as to satisfy the above-described relationship, the width of the first lead-out electrode 410 can be narrowed, and the Q value can be increased.

In addition, as described above, when the length of the first excitation electrode 210 in the X-axis direction is denoted by Ex and the length of the first portion 411 of the first lead-out electrode 410 in the X-axis direction is Hx, it is more preferable to satisfy a relationship of 0<Hx/Ex≤0.09.

In this case, the length Ex of the first excitation electrode 210 in the X-axis direction is, for example, 562 μm. The length Hx of the first lead-out electrode 410A in the X-axis direction is, for example, 50 μm or less. According to this configuration, since the first lead-out electrode 410 is set so as to satisfy the above-described relationship, the width of the first lead-out electrode 410 can be narrowed, and the Q value can be increased. In addition, by narrowing the width of the first lead-out electrode 410, it is possible to miniaturize the resonator element 10 and the resonator device 1.

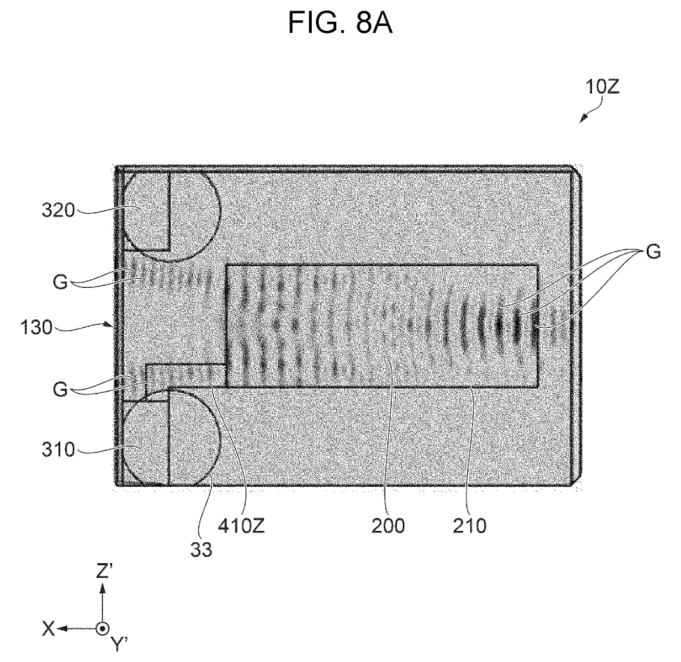

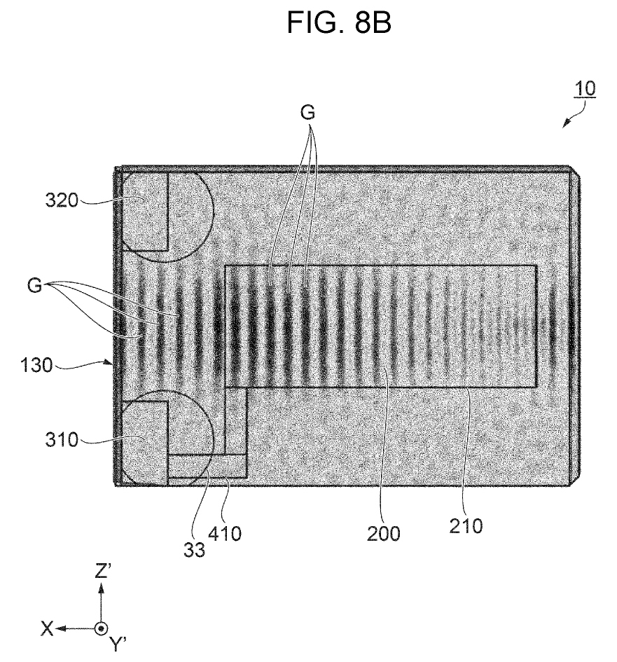

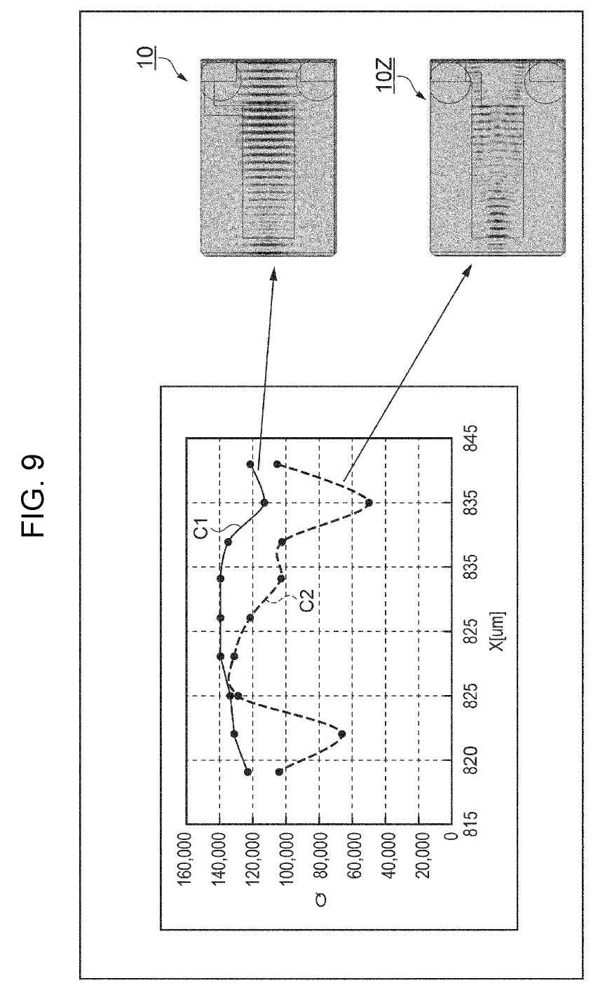

Next, with reference to FIGS. 8A, 8B, and 9, the spurious resonance mode influence and the Q values in the resonator element 10Z according to the related art and the spurious resonance mode influence and the Q values in the resonator element 10 of the present embodiment will be compared and described.

As shown in FIG. 8A, in the resonator element 10Z according to the related art, the first lead-out electrode 410Z is disposed between the first excitation electrode 210 and the first outer edge 130. In other words, the first lead-out electrode 410Z is disposed in the + X-axis direction of the first excitation electrode 210.

In the resonator element 10Z according to the related art, a spurious resonance mode G is transmitted to the first excitation electrode 210 in the X-axis direction, and it is found that the first lead-out electrode 410Z is affected by the spurious resonance mode G. As a result, it can be considered that vibrational energy leaks from the first lead-out electrode 410Z to the first mount electrode 310.

As shown in FIG. 8B, in the resonator element 10 of the present embodiment, the first lead-out electrode 410 is not disposed between the first excitation electrode 210 and the first outer edge 130. In other words, the first lead-out electrode 410 is disposed so as to avoid the non-electrode region 500 (refer to FIG. 3) in the + X-axis direction of the first excitation electrode 210.

In the resonator element 10 of the present embodiment, it is found that the spurious resonance mode G is transmitted to the first excitation electrode 210 in the X-axis direction as in the related art, but the first lead-out electrode 410 is not affected by the spurious resonance mode G. As a result, it can be considered that vibrational energy does not easily leak from the first lead-out electrode 410 to the first mount electrode 310.

Further, the graph shown in FIG. 9 shows the Q values C2 of the resonator element 10Z according to the related art and the Q values C1 of the resonator element 10 of the present embodiment for each region of the resonator element 10 and 10Z. As shown in FIG. 9, it is found that the resonator element 10 of the present embodiment exhibits stable Q values over the entire region as compared with the resonator element 10Z of the related art. In addition, it is found that the resonator element 10 of the present embodiment exhibits high Q values as a whole without a significant decrease in the Q values depending on the region.

As described above, since the first lead-out electrode 410 is disposed so as to avoid the non-electrode region 500 in the X-axis direction of the first excitation electrode 210, even when a spurious resonance mode is generated in the quartz crystal substrate 100, the first lead-out electrode 410 is not easily affected by the spurious resonance mode. Therefore, it is possible to suppress leakage of vibrational energy from the first lead-out electrode 410, and it is possible to obtain a stable Q value, for example, a value equal to or greater than 100K.

As described above, the resonator element 10 of the present embodiment includes: the quartz crystal substrate 100 having the first surface 110 along the X-axis and the Z'-axis of a quartz crystal and having a quadrangular shape in plan view including the first outer edge 130 intersecting the X-axis; the first excitation electrode 210 disposed on the first surface 110 of the quartz crystal substrate 100 and having a quadrangular shape in plan view including the first side 211 intersecting the X-axis; the first mount electrode 310 disposed on the side of the first outer edge 130 of the quartz crystal substrate 100 and connected to the first excitation electrode 210; and the first lead-out electrode 410 connecting the first excitation electrode 210 and the first mount electrode 310. The resonator element 10 has the non-electrode region 500, in which the quartz crystal substrate 100 is exposed, between the first outer edge 130 of the quartz crystal substrate 100 and the first side 211 of the first excitation electrode 210.

According to this configuration, since the non-electrode region 500, in which the quartz crystal substrate 100 is exposed, is provided between the first outer edge 130 and the first side 211, in other words, since the first lead-out electrode 410 is not provided between the first outer edge 130 and the first side 211, even when a spurious resonance mode is generated in the quartz crystal substrate 100, the first lead-out electrode 410 is not easily affected by the spurious resonance mode. Therefore, it is possible to suppress leakage of vibrational energy from the first lead-out electrode 410 to, for example, the first mount electrode 310, and it is possible to obtain a stable Q value.

Further, even when each dimension of the resonator element 10 varies, since the first lead-out electrode 410 is provided so as not to be coupled to the spurious resonance mode, it is possible to suppress deterioration of the Q value, and it is possible to easily manufacture the resonator element 10.

In the resonator element 10 according to the present embodiment, it is preferable that the first mount electrode 310 connected to the first lead-out electrode 410 is disposed on the side of the first outer edge 130, the first excitation electrode 210 has the second side 212 and the third side 213 intersecting the first side 211, and the first lead-out electrode 410 has the first portion 411 extending from the second side 212 or the third side 213 along the Z'-axis and the second portion 412 extending from the first portion 411 along the X-axis and connected to the first mount electrode 310. According to this configuration, since the first lead-out electrode 410 having the first portion 411 and the second portion 412 is provided, that is, the first lead-out electrode 410 is disposed so as not to be provided between the first outer edge 130 and the first side 211, even when a spurious resonance mode is generated in the quartz crystal substrate 100, it is possible to suppress the influence of the spurious resonance mode on the first lead-out electrode 410.

In the resonator element 10 according to the present embodiment, it is preferable that the first excitation electrode 210 has the fourth side 214 facing the first side 211 and intersecting the second side 212 and the third side 213, and when a length of the first excitation electrode 210 in the X-axis direction is denoted by Ex, a distance in the X-axis direction between the first portion 411 of the first lead-out electrode 410A and the first side 211 of the first excitation electrode 210 is denoted by D1, and a distance in the X-axis direction between the first portion 411 of the first lead-out electrode 410B and the fourth side 214 of the first excitation electrode 210 is denoted by D2, it is preferable that a relationship of 0≤D1/Ex≤0.18 or 0≤D2/Ex≤0.18 is satisfied. According to this configuration, since the arrangement of positions of the first lead-out electrodes 410A and 410B is set so as to satisfy the relationship of the above expression, it is possible to suppress the influence of the spurious resonance mode on the first lead-out electrodes 410A and 410B, and it is possible to obtain the stable Q value.

In the resonator element 10 according to the present embodiment, it is preferable that the length Hx of the first portion 411 of the first lead-out electrode 410A in the X-axis direction is shorter than the length D3 of the first excitation electrode 210 in the Z'-axis direction. According to this configuration, since the length Hx of the first portion 411 of the first lead-out electrode 410A in the X-axis direction is shorter than the length D3 of the first excitation electrode 210 in the Z'-axis direction, that is, since the width of the first lead-out electrode 410A is narrow, the Q value can be increased.

In the resonator element 10 according to the present embodiment, it is preferable that the length Hx of the first portion 411 of the first lead-out electrode 410 in the X-axis direction is shorter than the length D4 of the first mount electrodes 310A in the Z'-axis direction. According to this configuration, since the length Hx of the first portion 411 of the first lead-out electrode 410 in the X-axis direction is shorter than the length D4 of the first mount electrode 310A in the Z'-axis direction, that is, since the width of the first lead-out electrode 410 is narrow, the Q value can be increased. In addition, it is possible to increase the size of the first mount electrode 310A to the extent that the first mount electrode 310A does not overlap the non-electrode region 500, and for example, the conductivity with the bonding member 33 cab be increased.

In the resonator element 10 according to the present embodiment, when the length of the first excitation electrode 210 in the X-axis direction is denoted by Ex and the length of the first portion 411 of the first lead-out electrode 410A in the X-axis direction is denoted by Hx, it is preferable to satisfy a relationship of 0<Hx/Ex≤0.18. According to this configuration, since the first lead-out electrode 410A is set so as to satisfy the above-described relationship, the width of the first lead-out electrode 410 can be narrowed, and the Q value can be increased.

In the resonator element 10 according to the present embodiment, when the length of the first excitation electrode 210 in the X-axis direction is denoted by Ex and the length of the first portion 411 of the first lead-out electrode 410A in the X-axis direction is denoted by Hx, it is preferable to satisfy a relationship of 0<Hx/Ex≤0.09. According to this configuration, since the first lead-out electrode 410A is set so as to satisfy the above-described relationship, the width of the first lead-out electrode 410A can be narrowed, and the Q value can be increased.

In the resonator element 10 according to the present embodiment, it is preferable that the surface includes the first surface 110 and the second surface 120 having a front-back relationship, the excitation electrode 200 includes the first excitation electrode 210 disposed on the first surface 110 and the second excitation electrode 220 disposed on the second surface 120, and the mount electrode 300 includes the first mount electrode 310 connected to the first excitation electrode 210, the second mount electrode 320 connected to the second excitation electrode 220, the first mount electrode 310 is disposed on one side in the Z'-axis direction of the non-electrode region 500, and the second mount electrode 320 is disposed on the other side in the Z'-axis direction of the non-electrode region 500. According to this configuration, the first mount electrode 310 is disposed on one side and the second mount electrode 320 is disposed on the other side with respect to the non-electrode region 500, therefore, even when a spurious resonance mode is generated in the quartz crystal substrate 100, the first mount electrode 310 and the second mount electrode 320 are not easily affected by the spurious resonance mode. Therefore, a stable Q value can be obtained.

In the resonator element 10 according to the present embodiment, it is preferable that the lead-out electrode 400 includes a first lead-out electrode 410 which is disposed on the first surface 110 and connects the first excitation electrode 210 and the first mount electrode 310, and a second lead-out electrode 420 which is disposed on the second surface 120 and connects the second excitation electrode 220 and the second mount electrode 320. According to this configuration, since the first lead-out electrode 410 is disposed on the first surface 110 and the second lead-out electrode 420 is disposed on the second surface 120, even when a spurious resonance mode is generated in the quartz crystal substrate 100, the first lead-out electrode 410 and the second lead-out electrode 420 are not easily affected by the spurious resonance mode. Therefore, a stable Q value can be obtained.

In addition, the resonator device 1 according to the present embodiment includes the resonator elements 10, 10A, and 10B described above and includes the base substrate 24 to which the resonator elements 10, 10A, and 10B are attached. According to this configuration, it is possible to provide the resonator device 1 capable of obtaining a stable Q value.

In addition, it is preferable that the resonator device 1 according to the present embodiment includes the mounting pad 30 provided on the base substrate 24 and the bonding member 33 which connects the mount electrode 300 and the mounting pad 30, and the bonding member 33 is disposed at a position which does not overlap the non-electrode region 500 in plan view. According to this configuration, since the bonding member 33 is disposed at a position which does not overlap the non-electrode region 500, even when a spurious resonance mode is generated in the quartz crystal substrate 100, the bonding member 33 is not easily affected by the spurious resonance mode. Therefore, it is possible to suppress leakage of vibrational energy, and a stable Q value can be obtained.

What is claimed is:

1. A resonator element comprising:
a quartz crystal substrate having a surface along an X-axis and a Z'-axis of a quartz crystal and having a quadrangular shape in plan view including a first outer edge intersecting the X-axis;
an excitation electrode disposed on the surface of the quartz crystal substrate and having a quadrangular shape in plan view including a first side intersecting the X-axis;
a mount electrode disposed on a side of the first outer edge of the quartz crystal substrate and connected to the excitation electrode; and
an lead-out electrode connecting the excitation electrode and the mount electrode, and
the resonator element further having:
a non-electrode region between the first outer edge of the quartz crystal substrate and the first side of the excitation electrode, wherein the quartz crystal substrate is exposed.

2. The resonator element according to claim 1, wherein
the mount electrode connected to the lead-out electrode is disposed on a side of the first outer edge,
the excitation electrode has a second side and a third side intersecting the first side, and
the lead-out electrode has
a first portion extending from the second side or the third side along the Z'-axis, and
a second portion extending from the first portion along the X-axis and connected to the mount electrode.

3. The resonator element according to claim 2, wherein
the excitation electrode has a fourth side facing the first side and intersecting the second side and the third side,
a length of the excitation electrode in the X-axis direction is denoted by Ex,
a distance in the X-axis direction between the first portion of the lead-out electrode and the first side of the excitation electrode is denoted by D1, and
a distance in the X-axis direction between the first portion of the lead-out electrode and the fourth side of the excitation electrode is denoted by D2,
wherein a relationship of 0≤D1/Ex≤0.18 or 0≤D2/Ex≤0.18 is satisfied.

4. The resonator element according to claim 2, wherein
a length of the first portion of the lead-out electrode in the X-axis direction is shorter than a length of the excitation electrode in the Z'-axis direction.

5. The resonator element according to claim 2, wherein
a length of the first portion of the lead-out electrode in the X-axis direction is shorter than a length of the mount electrode in the Z'-axis direction.

6. The resonator element according to claim 2, wherein
a length of the excitation electrode in the X-axis direction is denoted by Ex, and
a length of the first portion of the lead-out electrode in the X-axis direction is denoted by Hx,
wherein a relationship of 0<Hx/Ex≤0.18 is satisfied.

7. The resonator element according to claim 2, wherein
a length of the excitation electrode in the X-axis direction is denoted by Ex, and
a length of the first portion of the lead-out electrode in the X-axis direction is denoted by Hx,
wherein a relationship of 0<Hx/Ex≤0.09 is satisfied.

8. The resonator element according to claim 1, wherein
the surface includes a first surface and a second surface having a front-back relationship,
the excitation electrode includes a first excitation electrode disposed on the first surface and a second excitation electrode disposed on the second surface,
the mount electrode includes a first mount electrode connected to the first excitation electrode and a second mount electrode connected to the second excitation electrode,
the first mount electrode is disposed on one side in the Z'-axis direction of the non-electrode region, and
the second mount electrode is disposed on the other side in the Z'-axis direction of the non-electrode region.

9. The resonator element according to claim 8, wherein
the lead-out electrode includes
a first lead-out electrode disposed on the first surface and connecting the first excitation electrode and the first mount electrode, and
a second lead-out electrode disposed on the second surface and connecting the second excitation electrode and the second mount electrode.

10. A resonator device comprising:
the resonator element according to claim 1; and
a base substrate to which the resonator element is attached.

11. The resonator device according to claim 10, further comprising:
a terminal provided on the base substrate; and
a bonding member connecting the mount electrode and the terminal, wherein
the bonding member is disposed at a position not overlapping the non-electrode region in plan view.
